(19) United States
(12) Patent Application Publication
(10) Pub. No.: US 2012/0313186 A1
(43) Pub. Date: Dec. 13, 2012

(54) POLYSILICON GATE WITH NITROGEN DOPED HIGH-K DIELECTRIC AND SILICON DIOXIDE

(75) Inventors: Ching-Chien HUANG, Kaohsiung City (TW); Ying-Han CHIOU, Tainan City (TW); Ling-Sung WANG, Tainan City (TW)

(73) Assignee: TAIWAN SEMICONDUCTOR MANUFACTURING COMPANY, LTD., Hsinchu (TW)

(21) Appl. No.: 13/156,006

(22) Filed: Jun. 8, 2011

(51) Int. Cl. H01L 29/78; H01L 21/28

(52) U.S. Cl. 257/411; 438/591; 257/E29.255; 257/E21.19

(57) ABSTRACT

A polysilicon gate structure includes a substrate, a silicon dioxide layer disposed over the substrate, a nitrogen-doped high-k dielectric layer disposed over the silicon dioxide layer, and a polysilicon gate disposed over the nitrogen-doped high-k dielectric layer.

### TECHNICAL FIELD

The present disclosure relates generally to an integrated circuit, and more particularly to a polysilicon gate.

### BACKGROUND

Polysilicon is widely used for integrated circuits as the conducting gate material in metal-oxide-semiconductor field-effect transistor (MOSFET) and complementary metal-oxide-semiconductor (CMOS) processing technologies. The polysilicon gate is usually heavily doped with n-type or p-type dopant materials. However, in a polysilicon gate structure having a silicon dioxide (SiO₂) gate dielectric layer, the polysilicon dopant material, e.g., boron for a p+ polysilicon gate, diffuses through the SiO₂ layer and into the channel region in the substrate under the SiO₂ layer. This contributes to poly depletion lowering the driving current of the device.

### BRIEF DESCRIPTION OF THE DRAWINGS

Reference is now made to the following descriptions taken in conjunction with the accompanying drawings, in which:

FIG. 1 is a diagram showing an exemplary polysilicon gate with nitrogen doped high-k dielectric and silicon dioxide according to some embodiments; and

FIG. 2 is a flowchart for the method of fabricating the exemplary polysilicon gate shown in FIG. 1 according to some embodiments.

### DETAILED DESCRIPTION

The making and using of various embodiments are discussed in detail below. It should be appreciated, however, that the present disclosure provides many applicable inventive concepts that can be embodied in a wide variety of specific contexts. The specific embodiments discussed are merely illustrative of specific ways to make and use, and do not limit the scope of the disclosure.

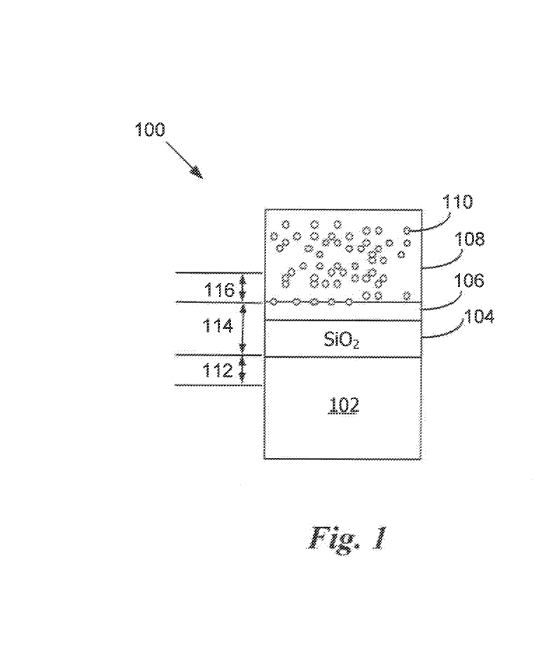

FIG. 1 is a diagram showing an exemplary polysilicon gate with nitrogen doped high-k dielectric and silicon dioxide according to some embodiments. The polysilicon gate structure 100 shows a substrate 102, a SiO₂ layer 104, a nitrogen-doped high-k dielectric layer 106, a polysilicon gate 108, and polysilicon gate dopants 110. In some embodiments, the substrate 102 includes silicon. In some other embodiments, the substrate 102 may alternatively or additionally include other elementary semiconductor, such as germanium. The substrate 102 may also include a compound semiconductor, such as silicon carbide, gallium arsenide, indium arsenide, indium phosphide, or any other suitable material.

The substrate 102 may include an epitaxial layer. For example, the substrate 102 may have an epitaxial layer overlying a bulk semiconductor. Further, the substrate 102 may be strained for performance enhancement. For example, the epitaxial layer may include semiconductor materials different from those of the bulk semiconductor such as a layer of silicon germanium overlying bulk silicon, or a layer of silicon overlying a bulk silicon germanium formed by a process including selective epitaxial growth (SEG). Furthermore, the substrate 102 may include a semiconductor-on-insulator (SOI) structure. In various embodiments, the substrate 102 includes a buried oxide (BOX) layer formed by a process such as separation by implanted oxygen (SIMOX).

In some embodiments, the substrate 102 can include various doped wells and other doped features configured and coupled to form various microelectronic devices such as metal-insulator-semiconductor field effect transistors (MOSFET) including complementary MOSFET (CMOS), imaging sensor including CMOS imaging sensors (CIS), micro-electro-mechanical systems (MEMS), and/or other suitable active and/or passive devices. The doped wells and other doped features include p-type doped region and/or an n-type doped region, formed by a doping process such as ion implantation.

The SiO₂ layer 104 and the nitrogen-doped high-k dielectric layer 106 form the gate insulator. A high quality SiO₂ film can be obtained by a thermal oxidation of silicon. A thermal SiO₂, forms smooth, low-defect interface with silicon, and can be also deposited by chemical vapor deposition (CVD).

The nitrogen-doped high-k dielectric layer 106 includes dielectric material having a high dielectric constant k compared to about 3.9 of SiO₂, e.g., HfON. The nitrogen-doped high-k dielectric layer 106 can be formed by depositing high-k dielectric material, e.g., HfO₂, HfSiO₄, ZrO₂, ZrSiO₄, etc, and then nitrogen-doping the high-k dielectric material. The high-k dielectric material may be deposited using, e.g., a chemical vapor deposition (CVD), or physical vapor deposition (PVD) process.

In some embodiments, the nitrogen doping is performed by a plasma nitridation with N₂ plasma (Decoupled Plasma Nitridation, NPN), which could incorporated nitrogen at the top surface of high-k dielectric layer to form the nitrogen-doped high-k dielectric layer 106 in order to prevent the polysilicon gate dopant 110 material (e.g., boron) diffusion into the SiO₂ layer 104 and the device channel area 112 in the substrate 102. The nitrogen-doped high-k dielectric layer 106 has a nitrogen dosage of about 8-9% in some embodiments.

In some embodiments, the thickness of SiC)₂ layer 104 can be about 15 Å to about 45 Å, while the thickness of the high-k gate dielectric layer 106 can be about 4 Å to about 12 Å. The thickness of each of the SiO₂ layer 104 and the nitrogen-doped high-k dielectric layer 106 can be adjusted for each application, as well as the thickness ratio of the two layers 104 and 106. For example, the thickness ratio of the nitrogen-doped high-k dielectric layer 106 and the silicon dioxide layer 104 is about 1:4 in some embodiments. In other embodiments, the ratio can be different values, e.g., 1:3, 1:5, etc.

The polysilicon gate 108 is doped with n-type and/or p-type semiconductor material. For the n-type semiconductor material, the doping atoms usually have one more valence electron than the host atoms. One example is doping group IV elements (e.g., silicon, germanium, or tin, having four valence electrons) with group V elements (phosphorus, arsenic, or antimony, having five valence electrons). For the p-type semiconductor material, group iii elements (e.g., boron, aluminium, indium, or gallium, having three valence electrons) can be used to dope group IV elements (e.g., silicon, having four valence electrons).

Without the nitrogen-doped high-k dielectric layer 106, some polysilicon gate dopant 110, e.g., boron, may diffuse into the gate dielectric region 114 and the device channel region 112 in the substrate 102. The boron diffusion into the device channel region 112 results in the device threshold voltage (Vt) shift, The boron diffusion accumulated at the gate dielectric region 114 results in bulk electron-traps to interfere with effective gate control. The boron diffusion out of the polysilicon gate interface 116 contributes to polysilicon depletion, which lowers the gate dielectric capacitance (Cₒₓ) and the driving current.

By using the nitrogen-doped high-k dielectric layer 106, e.g., HfON, the boron diffusion is effectively blocked. Also, a leakage current through the gate dielectric is reduced, and the equivalent oxide thickness (EOT) can be controlled to a desired specification at the same time. This results in increased driving current, e.g., 20-30% increase of on/off current ratio (Iₒₙ/I_{off}) with a thickness ratio of about 1:4 between the nitrogen-doped high-k dielectric layer 106 and the silicon dioxide layer 104 in some embodiments. Also, when silicon is used for the substrate 102, the SiO₂ layer 104 provides an excellent interface with the silicon substrate 102 with low interface trap density.

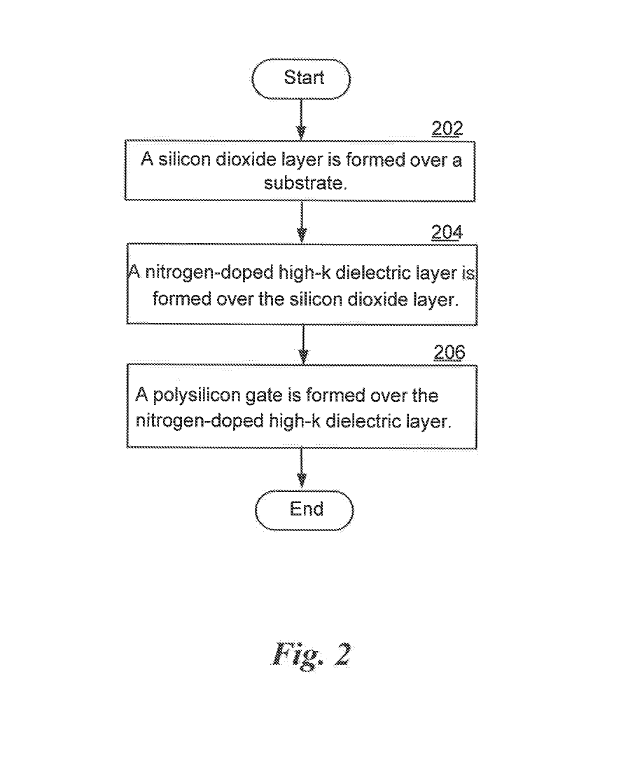

FIG. 2 is a flowchart for the method of fabricating the exemplary polysilicon gate shown in FIG. 1 according to some embodiments. At step 202, a silicon dioxide layer is formed over a substrate. At step 204, a nitrogen-doped high-k dielectric layer is formed over the silicon dioxide layer. At step 206, a polysilicon gate is formed over the nitrogen-doped high-k dielectric layer.

In various embodiments, forming the nitrogen-doped high-k dielectric layer includes depositing a high-k dielectric layer over the silicon dioxide layer and doping the high-k dielectric layer with nitrogen. For example, a plasma nitridation can be performed by N₂ plasma (Decoupled Plasma Nitridation, DPN), which could incorporated nitrogen at the top surface of the high-k dielectric layer to prevent polysilicon gate dopant diffusion into the silicon dioxide layer and the device channel area in the substrate. The high-k dielectric layer is doped with a nitrogen dosage from about 8% to about 9% in some embodiments.

Forming the polysilicon gate includes depositing a polysilicon layer over the nitrogen-doped high-k dielectric layer and doping the polysilicon layer with a semiconductor dopant. The semiconductor dopant is a p-type semiconductor material in some embodiments, e.g., boron. The semiconductor dopant is an n-type semiconductor material in some other embodiments. A thickness ratio of the nitrogen-doped high-k dielectric layer and the silicon dioxide layer is about 1:4 in some embodiments. In other embodiments, the ratio can be different values, e.g., 1:3, 1:5, etc.

According to some embodiments, a polysilicon gate structure includes a substrate, a silicon dioxide layer disposed over the substrate, a nitrogen-doped high-k dielectric layer disposed over the silicon dioxide layer, and a polysilicon gate disposed over the nitrogen-doped high-k dielectric layer.

According to some embodiments, a method of fabricating a polysilicon gate structure includes forming a silicon dioxide layer over a substrate. A nitrogen-doped high-k dielectric layer is formed over the silicon dioxide layer. A polysilicon gate is formed over the nitrogen-doped high-k dielectric layer.

A skilled person in the art will appreciate that there can be many embodiment variations of this disclosure. Although the embodiments and their features have been described in detail, it should be understood that various changes, substitutions and alterations can be made herein without departing from the spirit and scope of the embodiments. Moreover, the scope of the present application is not intended to be limited to the particular embodiments of the process, machine, manufacture, and composition of matter, means, methods and steps described in the specification. As one of ordinary skill in the art will readily appreciate from the disclosed embodiments, processes, machines, manufacture, compositions of matter, means, methods, or steps, presently existing or later to be developed, that perform substantially the same function or achieve substantially the same result as the corresponding embodiments described herein may be utilized according to the present disclosure.

The above method embodiment shows exemplary steps, but they are not necessarily required to be performed in the order shown, Steps may be added, replaced, changed in order, and/or eliminated as appropriate, in accordance with the spirit and scope of embodiment of the disclosure. Embodiments that combine different claims and/or different embodiments are within the scope of the disclosure and will be apparent to those skilled in the art after reviewing this disclosure.

What is claimed is:

1. A polysilicon gate structure, comprising:
a substrate;
a silicon dioxide layer disposed over the substrate;
a nitrogen-doped high-k dielectric layer disposed over the silicon dioxide layer; and
a polysilicon gate disposed over the nitrogen-doped high-k dielectric layer.

2. The polysilicon gate structure of claim 1, wherein the substrate comprises silicon.

3. The polysilicon gate structure of claim 1, wherein the nitrogen-doped high-k dielectric layer comprises HfON.

4. The polysilicon gate structure of claim 1, wherein the polysilicon gate includes a p-type semiconductor material.

5. The polysilicon gate structure of claim 4, wherein the p-type semiconductor material is boron.

6. The polysilicon gate structure of claim 1, wherein the polysilicon gate includes an n-type semiconductor material.

7. The polysilicon gate structure of claim 1, wherein the nitrogen-doped high-k dielectric layer is doped with a nitrogen dosage from about 8% to about 9%.

8. The polysilicon gate structure of claim 1, wherein a thickness ratio of the nitrogen-doped high-k dielectric layer and the silicon dioxide layer is about 1:4.

9. The polysilicon gate structure of claim 1, wherein a thickness of the nitrogen-doped high-k dielectric layer is about 4 Å to about 12 Å.

10. The polysilicon gate structure of claim 1, wherein a thickness of the silicon dioxide layer is about 15 Å to about 45 Å.

11. A method of fabricating a polysilicon gate structure, comprising:
forming a silicon dioxide layer over a substrate;
forming a nitrogen-doped high-k dielectric layer over the silicon dioxide layer; and
forming a polysilicon gate over the nitrogen-doped high-k dielectric layer.

12. The method of claim 11, wherein forming the nitrogen-doped high-k dielectric layer comprises:
depositing a high-k dielectric layer over the silicon dioxide layer; and
doping the high-k dielectric layer with nitrogen.

13. The method of claim 12, wherein the high-k dielectric layer with nitrogen is doped with a nitrogen dosage from about 8% to about 9%.

14. The method of claim 11, wherein forming the polysilicon gate comprises:
depositing a polysilicon layer over the nitrogen-doped high-k dielectric layer; and
doping the polysilicon layer with a semiconductor dopant.

15. The method of claim of claim 14, wherein the semiconductor dopant is a p-type semiconductor material.

16. The method of claim of claim 15, wherein the semiconductor dopant is boron.

17. The method of claim of claim 14, wherein the semiconductor dopant is an n-type semiconductor material.

18. The method of claim 11, wherein a thickness ratio of the nitrogen-doped high-k dielectric layer and the silicon dioxide layer is about 1:4.

19. An integrated circuit having a polysilicon gate structure, comprising:
a silicon substrate;
a silicon dioxide layer disposed over the silicon substrate;
a nitrogen-doped high-k dielectric layer disposed over the silicon dioxide layer; and
a polysilicon gate including boron disposed over the nitrogen-doped high-k dielectric layer.

20. The integrated circuit of claim 19, wherein the nitrogen-doped high-k dielectric layer comprises HfON.
